(19) United States
(12) Patent Application Publication
(10) Pub. No.: US 2024/0244810 A1
(43) Pub. Date: Jul. 18, 2024

(54) CASE

(71) Applicant: Murata Manufacturing Co., Ltd., Nagaokakyo-shi (JP)

(72) Inventor: Noboru SERITA, Nagaokakyo-shi (JP)

(21) Appl. No.: 18/619,238

(22) Filed: Mar. 28, 2024

Related U.S. Application Data
(63) Continuation of application No. PCT/JP2022/038046, filed on Oct. 12, 2022.

(30) Foreign Application Priority Data
Jan. 12, 2022 (JP) 2022-003090

(51) Int. Cl. H05K 13/02; H05K 7/18

(52) U.S. Cl. CPC H05K 13/028; H05K 7/18

(57) ABSTRACT

A case includes a case body including a discharge port through which electronic components are dischargeable, an upper guide slit and a lower guide slit communicating with the discharge port, and a shutter slidably inserted into the guide slits and movable to open and close the discharge port. The case body includes a front inner wall surface and a rear inner wall surface facing each other to define the upper guide slit therebetween and a lower inner wall surface and an upper inner wall surface defining the lower guide slit therebetween. The shutter includes a pair of first and second main surfaces, and includes, on at least one of the pair of main surfaces, an increased thickness portion extending in a sliding direction in which the shutter slides.

### CROSS REFERENCE TO RELATED APPLICATIONS

This application claims the benefit of priority to Japanese Patent Application No. 2022-003090 filed on Jan. 12, 2022 and is a Continuation Application of PCT Application No. PCT/JP2022/038046 filed on Oct. 12, 2022. The entire contents of each application are hereby incorporated herein by reference.

### BACKGROUND OF THE INVENTION

### 1. Field of the Invention

The present invention relates to cases for accommodating electronic components such as chip components.

### 2. Description of the Related Art

A mounting device is used to mount an electronic component at a predetermined position on a board. It is necessary to individually supply electronic components to such a mounting device. For example, Japanese Unexamined Patent Application Publication No. 2009-295618 discloses a case that accommodates a number of electronic components in bulk, and has, at a bottom thereof, a discharge port through which the electronic components are allowed to fall under their own weight onto a feeder. The feeder supplies the electronic components individually to a mounting device.

### SUMMARY OF THE INVENTION

If the case of type includes an opening/closing member that opens and closes the discharge port, minute electronic components may enter, for example, a gap between the opening/closing member and the case, so that the minute electronic components may be prevented from being smoothly discharged.

Example embodiments of the present invention provide cases that facilitate smooth discharge of components through a discharge port.

A case according to an example embodiment of the present invention includes a case body to accommodate a plurality of components and including a discharge port through which the components are dischargeable, a guide slit in the case body and communicating with the discharge port, and a shutter slidably inserted into the guide slit to slide to open and close the discharge port, the case body including a pair of inner wall surfaces that face each other and define the guide slit therebetween, the shutter including a pair of main surfaces that face the pair of inner wall surfaces, respectively, and including an increased thickness portion on at least one of the pair of main surfaces, the increased thickness portion extending in a sliding direction in which the shutter slides.

The example embodiments of the present invention provide cases that facilitate smooth discharge of components through a discharge port.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a perspective view of a case according to an example embodiment of the present invention as viewed from below.

FIG. 2 is a front view of a case according to an example embodiment of the present invention.

FIG. 3 is a bottom view of a case according to an example embodiment of the present invention.

FIG. 4 is a diagram illustrating the interior of a case according to an example embodiment of the present invention as viewed from a side.

FIG. 5 is diagram illustrating the interior of a front portion of a case according to an example embodiment of the present invention in an open state in which a discharge port of the case is open, as viewed from a side.

FIG. 6 illustrates the portion VI in FIG. 5 on an enlarged scale.

FIG. 7 illustrates the portion VII in FIG. 5 on an enlarged scale.

FIG. 8 is a partial cross-sectional view taken along the line VIII-VIII in FIG. 7.

FIG. 9 is a plane view of a shutter according to an example embodiment of the present invention.

FIG. 10 is a plane view of a further example of a shutter according to an example embodiment of the present invention.

FIG. 11 is a diagram illustrating a portion corresponding to the portion VII in FIG. 5.

FIG. 12 is a partial cross-sectional view taken along the line XII-XII in FIG. 11.

### DETAILED DESCRIPTION OF THE EXAMPLE EMBODIMENTS

### Example Embodiments

Example embodiments of the present invention will be described with reference to the drawings.

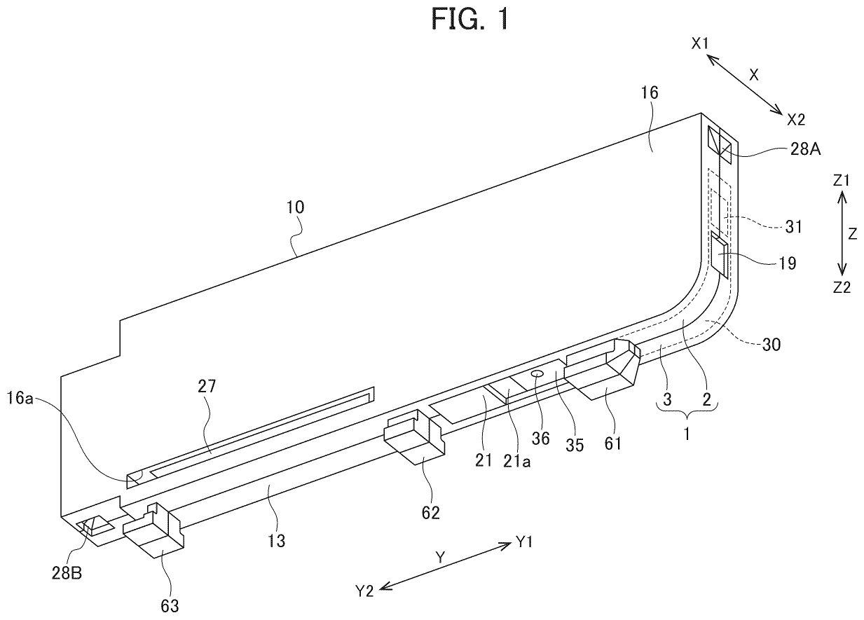

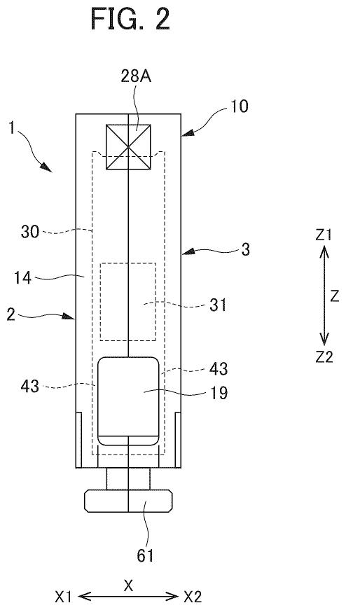

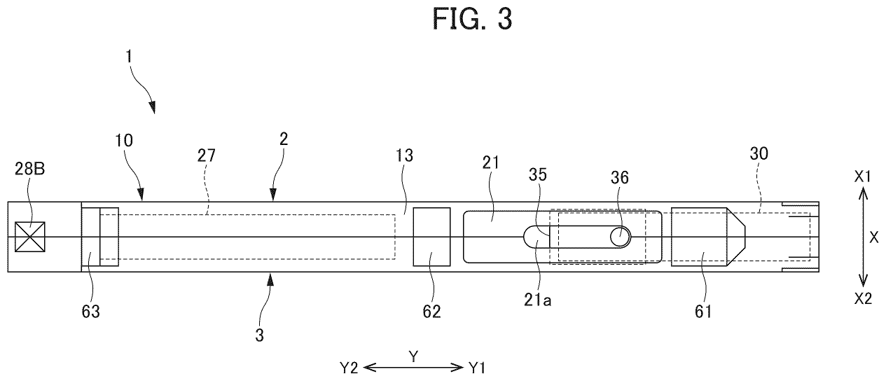

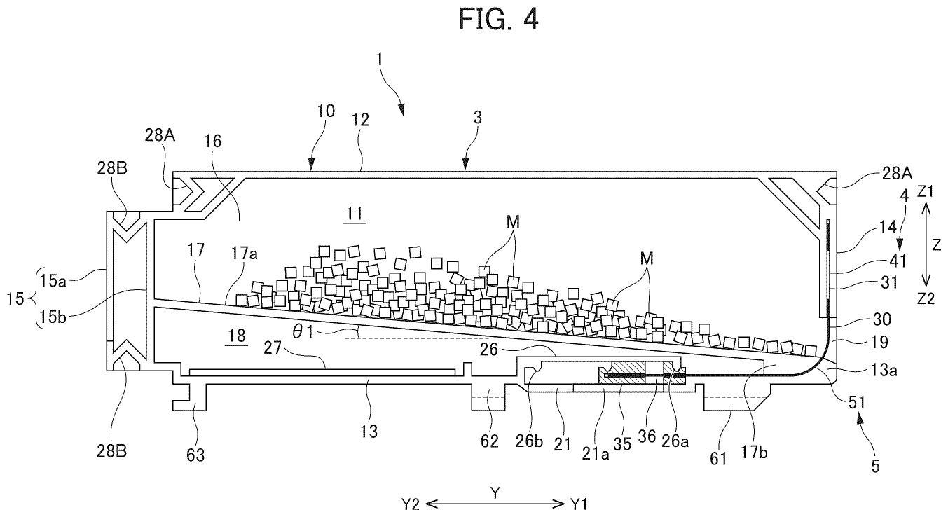

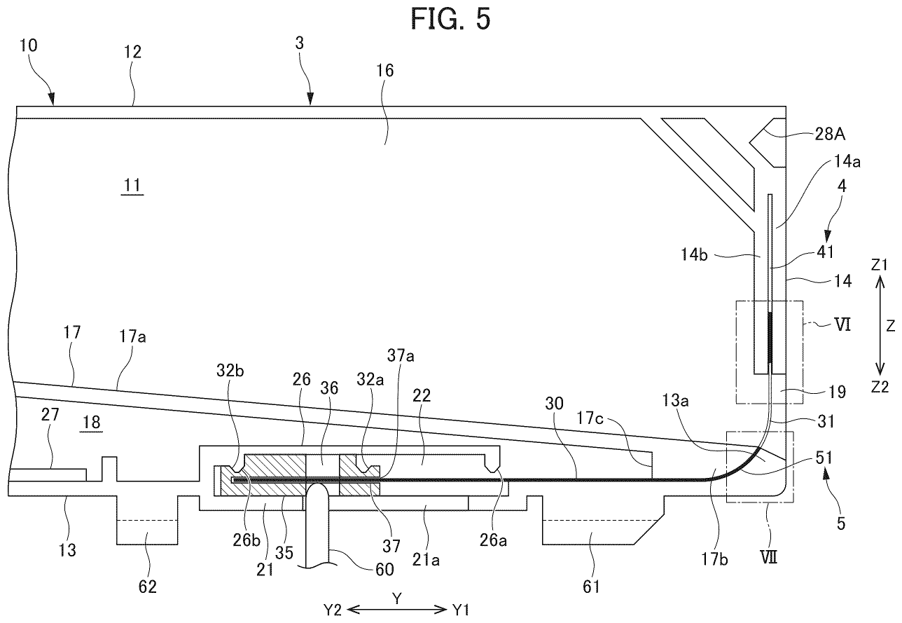

FIG. 1 is a perspective view of a case 1 according to the present example embodiment as viewed from below. FIG. 2 is a front view of the case 1 as viewed from front. FIG. 3 is a bottom view of the case 1. FIG. 4 is a diagram illustrating the interior of the case 1 as viewed from a side. FIG. 5 is diagram illustrating the interior of a front portion of the case 1 as viewed from a side.

As illustrated in FIG. 4, the case 1 accommodates therein a plurality of electronic components M in bulk as components. The case 1 having the plurality of electronic components M accommodated therein is set to a feeder (not shown), and the electronic components M are discharged from the case 1 due to vibration of the feeder and supplied to a mounting device or the like. The electronic component M of the present example embodiment is, for example, a minute rectangular parallelepiped electronic component having a length of about 1.2 mm or less in the longitudinal direction, for example. Examples of such an electronic component include a capacitor, an inductor, etc., but the present example embodiment is not limited thereto.

Arrows X, Y, and Z in the drawings to which reference is made respectively indicate the left-right direction (width direction), the front-rear direction, and the up-down direction of the case 1 in a use state where the case 1 is set to the feeder. The left side in the left-right direction X is denoted by X1, the right side is denoted by X2. The front side in the front-rear direction Y is denoted by Y1, the rear side is denoted by Y2. The upper side in the up-down direction Z is denoted by Z1, and the lower side is denoted by Z2. In the following description, the left-right direction, the front-rear direction, and the up-down direction are based on the directions indicated by the arrows.

As illustrated in FIGS. 1 to 4, the case 1 includes a case body 10 in which the plurality of electronic components M are accommodated, and a shutter 30.

As illustrated in FIG. 1, the case body 10 includes a first member 2 and a second member 3 that are separable in left-right direction. The first member 2 and the second member 3 are molded bodies made of resin such as ABS resin or the like. The first member 2 and the second member 3 are combined with and joined to each other to thereby form the case body 10. Examples of a process for joining the first member 2 and the second member 3 include, but are not limited to, ultrasonic bonding and bonding with an adhesive.

FIG. 4 illustrates the interior of the second member 3 situated on the right side, while the first member 2 situated on the left side is omitted. The case body 10 has a flat box shape that is long in the front-rear direction and thin in the left-right direction. In the following description, except where necessary, the first member 2 and the second member 3 will not be individually described, and the configuration including the first member 2 and the second member 3 joined to each other will be described.

As illustrated in FIG. 4, the case body 10 includes a top plate 12 and a bottom plate 13 that extend in the front-rear direction, a front wall 14 and a rear wall 15 that extend in the up-down direction, a pair of left and right side walls 16, and an inclined plate 17 that partitions the interior of the case body 10 into upper and lower spaces. The rear wall 15 includes an outer rear wall 15a defining an outer surface and an inner rear wall 15b provided forward of the outer rear wall 15a. The inner rear wall 15b is an example of a wall. An accommodating space 11 to accommodate the plurality of electronic components M in bulk is provided in the interior of the case body 10.

The electronic components M accommodated in the accommodating space 11 are discharged through a discharge port 19 to the outside of the case body 10. The discharge port 19 is provided in a lower portion of the front wall 14. The discharge port 19 is a rectangular opening. The discharge port 19 is not limited to the rectangular shape, and may have, for example, a circular shape, an elliptical shape, or the like. The discharge port 19 is opened and closed by the shutter 30.

The inclined plate 17 extends between the left and right side walls 16 and extends from the inner rear wall 15b to a lower portion of the discharge port 19. The inclined plate 17 is arranged below the center in the up-down direction of the interior of the case body 10. In the interior of the case body 10, the space above the inclined plate 17 serves as the accommodating space 11, and the space below the inclined plate 17 serves as a lower space 18.

As illustrated in FIG. 4, the inclined plate 17 is inclined downward toward the discharge port 19, and has an upper surface that is denoted as an inclined surface 17a and inclined downward toward the discharge port 19. In the present example embodiment, the inclined surface 17a is inclined by an inclination angle θ1 of, for example, about 10° with respect to the horizontal direction in a state in which the case 1 is set to the feeder. The inclination angle θ1 of the inclined surface 17a is preferably about 3° or greater and about 10° or less, for example. The inclination angle θ1 of the inclined surface 17a is appropriately adjusted in accordance with, for example, vibration conditions of the feeder. The inclined plate 17 includes, in a lower portion of a front end thereof, an upper guide protrusion 17b that defines a portion of a lower guide 5, which will be described later.

As illustrated in FIG. 4, a radio frequency identification (RFID) tag 27 having a strip shape elongated in the front-rear direction is provided in a rear portion of the lower space 18. The RFID tag 27 may be an adhesive label, for example, and is attached to the upper surface of the bottom plate 13. The RFID tag 27 is placed into the lower space 18 through a hole 16a in the side wall 16 shown in FIG. 1 and extending in the front-rear direction. The RFID tag 27 has a known configuration including a transmitter/receiver, a memory, an antenna, and the like. For example, the feeder, to which the case 1 is set, includes a reader/writer that reads and writes information from and to the RFID tag 27.

The case body 10 includes upper gripping portions 28A and rear gripping portions 28B. The upper gripping portions 28A include a pair of front and rear recesses at front and rear ends of an upper portion of the case body 10. The rear gripping portions 28B include a pair of upper and lower recesses at upper and lower ends of a rear portions of the case body 10. When the case 1 is carried by a robot hand, for example, the upper gripping portions 28A or the rear gripping portions 28B are gripped by the robot hand.

The case body 10 includes, on a bottom surface thereof, a plurality of claws that make it possible to detachably set the case 1 to the feeder. In the present example embodiment, a first claw 61, a second claw 62, and a third claw 63 are provided on the bottom surface at intervals in the front-rear direction. The first claw 61, the second claw 62, and the third claw 63 are formed integrally with the case body 10. Each of the first claw 61 and the second claw 62 includes a T-shaped slot having an inverted T-shaped cross section in a plane extending in the up-down direction and the left-right direction. The third claw 63 is a plate-shaped structure extending rearward and having an L-shape in a side view.

The shutter 30 slides to open and close the discharge port 19. The shutter 30 continuously extends from the upper surface of the bottom plate 13 to the interior of the front wall 14, and is slidable in the extending direction in which it extends. The bottom plate 13 has, at a front end thereof, a lower guide protrusion 13a that defines a portion of the lower guide 5, which will be described later.

The shutter 30 includes an elongated strip-shaped film with a constant width. The shutter 30 is made of a flexible material having a certain degree of rigidity and being bendable, such as PET (polyethylene terephthalate). The shutter 30, which includes such a film, may have any thickness, but the thickness is preferably about 0.1 mm or greater and about 0.5 mm or less, for example. The shutter 30 has a width that is slightly larger than the width of the discharge port 19, and is capable of covering the discharge port 19 without a gap. The shutter 30 has, at a front end portion thereof, an opening 31 having the same or substantially the same shape as the discharge port 19.

The shutter 30 can slide along an upper guide 4 and the lower guide 5 of the case body 10. The upper guide 4 is provided above the discharge port 19, and the lower guide 5 is provided below the inclined plate 17. A front portion of the shutter 30 slides in the up-down direction along the upper guide 4, and a rear portion of the shutter 30 slides in the horizontal or substantially horizontal direction along the lower guide 5. The upper guide 4 and the lower guide 5 each define a passage that slidably holds the shutter 30 while maintaining the plane direction of the shutter 30 along the left-right direction. Details of the upper guide 4 and the lower guide 5 will be described later.

The shutter 30 is slid via a slider 35. As illustrated in FIG. 4, the slider 35 is provided on a rear end portion of the shutter 30.

As illustrated in FIGS. 4 and 5, the bottom plate 13 of the case body 10 includes a protruding plate portion 21 in a front portion thereof. The protruding plate portion 21 protrudes downward and extends in the front-rear direction. The protruding plate portion 21 has an elongated hole 21a extending in the front-rear direction. A plate portion 26 is provided above the protruding plate portion 21 with a predetermined space 22 provided therebetween. The plate portion 26 is parallel or substantially parallel to the protruding plate portion 21, and is formed integrally with the bottom plate 13. The space 22 is surrounded by the protruding plate portion 21, the plate portion 26, and the left and right side walls 16. The slider 35 is provided in the space 22. The plate portion 26 includes, at a front end thereof, a front protrusion 26a protruding downward. The plate portion 26 includes, at a rear end thereof, a rear protrusion 26b protruding downward.

The slider 35 is a rectangular or substantially rectangular plate-shaped structure elongated in the front-rear direction. The slider 35 includes a circular or substantially circular operation hole 36 penetrating through the slider 35 in the up-down direction. The operation hole 36 communicates with the long hole 21a of the case body 10, and is exposed to the outside through the long hole 21a.

As illustrated in FIG. 5, the slider 35 includes a slit 37 in a middle in the up-down direction of the slider 35, extending in the front-rear direction, and opening at the front side of the slider 35. The slit 37 includes a front end opening 37a at the front end thereof, and the shutter 30 has the rear end portion inserted in the slit 37 through the front end opening 37a. The slit 37 has a closed rear end. The slit 37 may open at the left and right sides of the slider 35. The shutter 30 is fixed to the slider 35 by way of adhesion or the like. As a result, the shutter 30 can slide together with the slider 35. The slider 35 slides along, and is guided by, the protruding plate portion 21 and the plate portion 26 of the bottom plate 13 and the left and right side walls 16, and thereby slidingly moves in the front-rear direction.

As illustrated in FIG. 5, the slider 35 includes a front recess 32a and a rear recess 32b in a front end portion and a rear end portion of the upper surface, respectively. When the slider 35 slides forward, the front protrusion 26a of the plate portion 26 enters and engages with the front recess 32a, whereby further forward sliding is restricted. At this time, the shutter 30 is positioned such that the opening 31 is positioned above the discharge port 19 as illustrated in FIG. 4, and the discharge port 19 is closed by a portion of the shutter 30 below the opening 31.

On the other hand, when the slider 35 slides rearward, as illustrated in FIG. 5, the rear protrusion 26b of the plate portion 26 enters and engages with the rear recess 32b, whereby further rearward sliding is restricted. At this time, the opening 31 of the shutter 30 coincides with the discharge port 19, and the discharge port 19 is open.

After a predetermined number of electronic components M are charged into the accommodating space 11 through the discharge port 19, the case 1 is shipped to a supply destination of the electronic components M, while having the slider 35 slid forward and the discharge port 19 closed by the shutter 30. Thus, FIG. 4 illustrates the interior of the case 1 at the time of shipment. A user who receives the supply of the case 1 can open the discharge port 19 in the following manner, for example.

As illustrated in FIG. 5, the user inserts an operation pin 60 into the operation hole 36 of the slider 35, and moves the operation pin 60 in the direction for the shutter 30 to open the discharge port 19, i.e., in the rearward direction. As a result, the shutter 30 slides rearward in conjunction with the slider 35, and the opening 31 of the shutter 30 becomes coincident with the discharge port 19, thereby opening the discharge port 19.

The mechanism to slide the shutter 30 to open and close the discharge port 19 is not limited to the above-described configuration in which the slider 35 is integrated with the shutter 30, and a different mechanism may be adopted.

In the foregoing, the basic configuration of the case 1 according to the present example embodiment has been described. The case 1 is used, for example, as follows. After a predetermined number of electronic components M are charged into the accommodating space 11 of the case body 10 through the discharge port 19 opened in advance, the discharge port 19 is closed, and then, the case 1 is supplied to a predetermined supply destination. At the supply destination, as described above, the case 1 is set to the feeder and the discharge port 19 is opened, and the electronic components M are discharged through the discharge port 19 and supplied to the mounting device or the like by the vibration of the feeder.

Next, the upper guide 4 and the lower guide 5, which guide the sliding motion of the shutter 30, and the shutter 30 will be described in detail.

As illustrated in FIG. 5, the upper guide 4 includes an upper guide slit 41 as a guide slit that is provided above the discharge port 19 and extends in the up-down direction. The upper guide slit 41 is located in the front wall 14. The front wall 14 includes a front plate 14a and a rear plate 14b between which the upper guide slit 41 interposed.

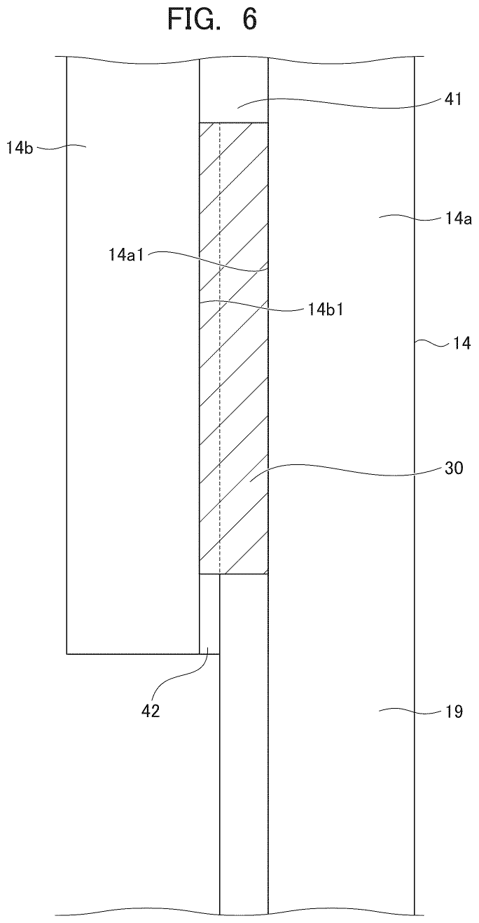

As illustrated in FIG. 6, the upper guide slit 41 communicates with the discharge port 19 through an opening 42 situated at the lower end of the upper guide slit 41. The front plate 14a and the rear plate 14b include a front inner wall surface 14a1 and a rear inner wall surface 14b1, respectively, which are a pair of inner wall surfaces facing each other. The upper guide slit 41 is defined between the front inner wall surface 14a1 and the rear inner wall surface 14b1. The shutter 30 includes a front end portion inserted into the upper guide slit 41 through the opening 42, and the front end portion slides in the upper guide slit 41 in the up-down direction.

As illustrated in FIG. 5, the lower guide 5 includes a lower guide slit 51 as a guide slit provided below the discharge port 19. The lower guide slit 51 is defined between the lower guide protrusion 13a of the bottom plate 13 and the upper guide protrusion 17b of the inclined plate 17.

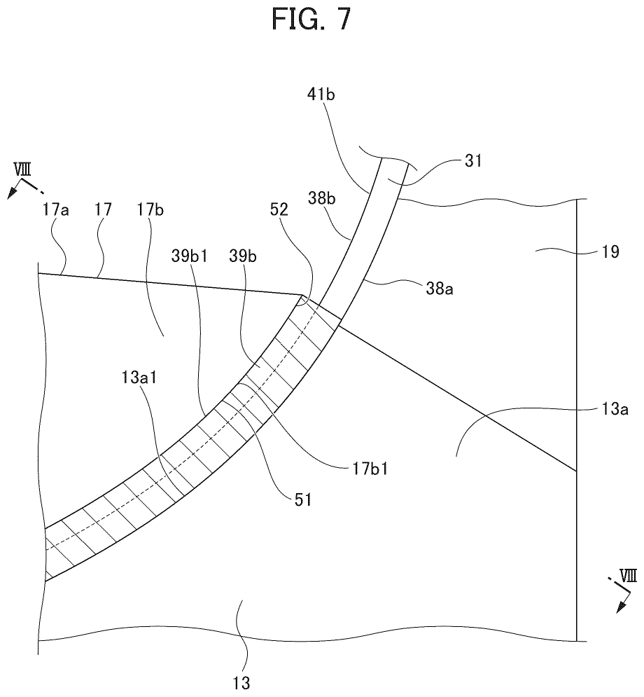

As illustrated in FIG. 7, the lower guide slit 51 communicates with the discharge port 19 through an opening 52 situated at the upper end of the lower guide slit 51. The lower guide protrusion 13a and the upper guide protrusion 17b include a lower inner wall surface 13a1 and an upper inner wall surface 17b1, respectively, which are a pair of inner wall surfaces facing each other. The lower guide slit 51 is defined between the lower inner wall surface 13a1 and the upper inner wall surface 17b1. The lower inner wall surface 13a1 on the side of the bottom plate 13 is curved to extend gently upwardly forward. The upper inner wall surface 17b1 on the side of the inclined plate 17 is curved in conformity with the lower inner wall surface 13a1 so that the thickness dimension of the lower guide slit 51 is substantially constant. Accordingly, the lower guide slit 51 is curved to extend gently upwardly forward.

A rear portion of the shutter 30 slides in the front-rear direction immediately above the bottom plate 13. A front end portion of the shutter 30 extending over the bottom plate 13 penetrates through and slides in the lower guide slit 51, which curves in a concave shape in the front-rear direction, whereby the end front portion is bent upward at an angle of approximately 90° with respect to the horizontal direction, and thereafter, transitions to a posture extending in the up-down direction.

As illustrated in FIG. 2, in a lower portion of the front wall 14, side guide slits 43 that communicate with the upper guide slit 41 and the lower guide slit 51 are provided on both left and right sides of a portion corresponding to the discharge port 19. Left and right edge portions of the shutter 30 extending over the discharge port 19 enter the side guide slits 43. Thus, the entire discharge port 19 can be closed by the shutter 30.

The upper guide slit 41 and the lower guide slit 51 have substantially the same thickness dimension that allows the shutter 30 to smoothly pass therethrough and to be held thereby. For example, the thickness dimension is about 1 to 2 times as large as the thickness of the shutter 30, and is preferably about 0.1 mm or greater and about 1 mm or less, for example.

As described above, the case body 10 is formed by combining the first member 2 and the second member 3, which are resin molded bodies arranged on the left and right. In the case of this type of resin molded body, a contact surface with the mold may be formed into a tapered shape as necessary in order to facilitate demolding by preventing formation of an undercut that can be caught by the mold at the time of removal of the molded body from the mold.

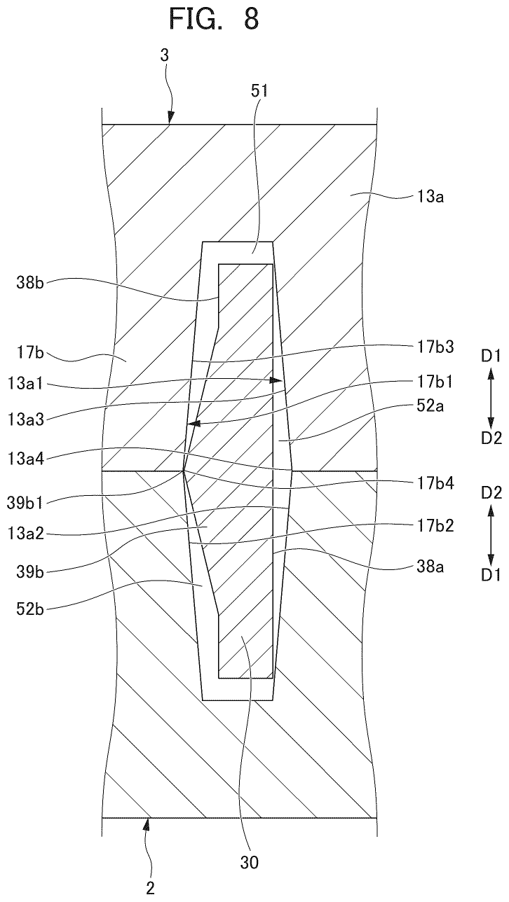

For example, as illustrated in FIG. 8, the lower inner wall surface 13a1 of the lower guide 5 includes a lower inner wall surface 13a2 of the first member 2 and a lower inner wall surface 13a3 of the second member 3, and the lower inner wall surfaces 13a2 and 13a3 are both tapered surfaces so that the lower guide slit 51 widens in a direction D2 that is opposite to a demolding direction D1. FIG. 8 is a cross-sectional view taken along the line VIII-VIII in FIG. 7, and illustrates the lower guide slit 51 and a peripheral portion thereof.

Furthermore, as illustrated in FIG. 8, the upper inner wall surface 17b1 of the lower guide 5 includes an upper inner wall surface 17b2 of the first member 2 and an upper inner wall surface 17b3 of the second member 3, and the upper inner wall surfaces 17b2 and 17b3 are both tapered surfaces so that the lower guide slit 51 widens in the direction D2 that is opposite to the demolding direction D1. Accordingly, the lower inner wall surface 13a1 and the upper inner wall surface 17b1 each define a groove having an isosceles triangular cross section. The lower inner wall surface 13a1 and the upper inner wall surface 17b1 include a groove bottom 13a4 and a groove bottom 17b4 at the center in the width direction, respectively.

In the upper guide 4, the front inner wall surface 14a1 and the rear inner wall surface 14b1 of the first member 2 and the second member 3 also preferably have a tapered shape, but illustration thereof is omitted herein.

As illustrated in FIGS. 7 and 8, the film-shaped shutter 30 includes a first main surface 38a and a second main surface 38b as a pair of main surfaces. Here, by referring to the position corresponding to the discharge port 19, the surface facing the front is denoted as the first main surface 38a, and the surface facing the rear is denoted as the second main surface 38b. The first main surface 38a faces downward and the second main surface 38b faces upward over the bottom plate 13.

The second main surface 38b includes a second increased thickness portion 39b as an increased thickness portion extending in the longitudinal direction of the shutter 30, that is, in a sliding direction in which the shutter 30 slides. The second increased thickness portion 39b includes a ridge that protrudes toward the interior of the case 1. The second increased thickness portion 39b preferably has an isosceles triangular shape in a transverse cross section, for example. The second increased thickness portion 39b is situated in a central portion in the width direction of the shutter 30. The second increased thickness portion 39b includes a second vertex 39b1 at the center in the width direction.

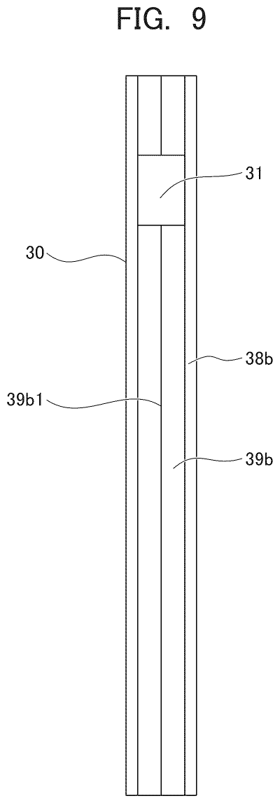

FIG. 9 illustrates the shutter 30 over the entire length, and is a plan view of the second main surface 38b. As illustrated in FIG. 9, the second increased thickness portion 39b is provided over the entire length of the shutter 30. The opening 31 makes the second increased thickness portion 39b partially discontinuous in the length direction.

As illustrated in FIG. 8, in the opening 52 of the lower guide slit 51, a front gap 52a is provided between the first main surface 38a of the shutter 30 and the lower inner wall surface 13a1. A rear gap 52b is provided between the second main surface 38b of the shutter 30 and the upper inner wall surface 17b1.

As illustrated in FIG. 8, when the shutter 30 inserted into the lower guide slit 51 is sliding to open or close the discharge port 19 of the case 1, the second vertex 39b1 of the second increased thickness portion 39b of the second main surface 38b may come into contact with the groove bottom 17b4 of the upper inner wall surface 17b1. Furthermore, both end portions of the first main surface 38a in the width direction may come into contact with the lower inner wall surface 13a1.

In the case 1 of the present example embodiment, the second increased thickness portion 39b of the shutter 30 is positioned in the rear gap 52b. As described above, the case 1 is set to the feeder, and the electronic components M are discharged through the discharge port 19. At this time, even if the electronic components M are minute enough to enter the rear gap 52b, the second increased thickness portion 39b that is present in the rear gap 52b reduces the tendency of the electronic components M to fall into the lower guide slit 51 through the rear gap 52b. Thus, smooth discharge of the electronic components M through the discharge port 19 is facilitated.

Furthermore, when the discharge port 19 is closed by the shutter 30 and during sliding of the shutter 30, the second increased thickness portion 39b is positioned in the rear gap 52b. This makes it less likely for the electronic components M to enter the rear gap 52b. Therefore, the shutter 30 can always slide smoothly. When the case 1 is transported or stored, the case 1 may be brought into not the same posture as in the use state in which the case 1 is set to the feeder, but a posture in which, for example, the discharge port 19 is oriented downward or the case 1 is placed upside down. In such a situation, the electronic components M may move toward the opening 42 of the upper guide slit 41. However, the second increased thickness portion 39b is positioned in the opening 42 of the upper guide slit 41 similarly to the lower guide slit 51, thereby making it less likely for the electronic components M to enter the opening 42. Therefore, the tendency of the electronic components M to enter the upper guide slit 41 is also reduced, and the shutter 30 can always slide smoothly. Furthermore, the electronic components M are less likely to enter the upper guide slit 41 and the lower guide slit 51 to be lost therein.

As illustrated in FIG. 8, when the vertex 39b1 of the second increased thickness portion 39b is in contact with the upper inner wall surface 17b1, the electronic components M are still less likely to fall into the lower guide slit 51. Furthermore, since the vertex 39b1 moves along the groove bottom 17b4, the shutter 30 can be smoothly slid.

As illustrated in FIG. 9, the second increased thickness portion 39b of the present example embodiment extends over the entire length of the shutter 30, i.e., the entire length in the sliding direction. Therefore, the second increased thickness portion 39b is reliably positioned in the opening 42 of the upper guide slit 41 and the opening 52 of the lower guide slit 51. Furthermore, when manufacturing the shutter 30, it is not necessary to form the second increased thickness portion 39b on separate portions of the shutter 30, thereby making the manufacturing easy.

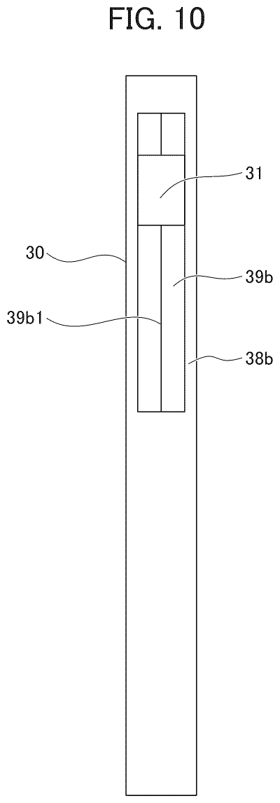

At least within a slide range from a position at which the shutter 30 closes the discharge port 19 to a position at which the shutter 30 leaves the discharge port 19 open, the second increased thickness portion 39b only has to be provided in correspondence with the opening 42 of the upper guide slit 41 and the opening 52 of the lower guide slit 51. Thus, as illustrated in FIG. 10, the second increased thickness portion 39b is not necessarily provided over the entire length of the shutter 30, but may be provided on a portion of the shutter 30. In this case, the length of the second increased thickness portion 39b is reduced or minimized, which provides an advantage that the material can be saved in manufacturing.

On the upper inner wall surface 17b1, the upper inner wall surface 17b2 of the first member 2 and having a tapered shape and the upper inner wall surface 17b3 of the second member 3 and having a tapered shape define the groove bottom 17b4 at the center in the width direction, and therefore, the rear gap 52b would originally be largest at the center in the width direction. On the other hand, the second increased thickness portion 39b, which is provided substantially at the center in the width direction of the shutter 30, effectively closes the rear gap 52b. Therefore, the second increased thickness portion 39b exerts a significant effect of reducing the tendency of the electronic components M to fall.

The case 1 according to the first example embodiment described above includes the case body 10 to accommodate a plurality of electronic components M and including the discharge port 19 through which the electronic components M are discharged, the upper guide slit 41 and the lower guide slit 51 in the case body 10 and communicating with the discharge port 19, and the shutter 30 that is slidably inserted into the upper guide slit 41 and the lower guide slit 51 and is slidable to open and close the discharge port 19. The case body 10 includes the front inner wall surface 14a1 and the rear inner wall surface 14b1 as a pair of inner wall surfaces facing each other to define the upper guide slit 41 therebetween, and the lower inner wall surface 13a1 and the upper inner wall surface 17b1 as a pair of inner wall surfaces defining the lower guide slit 51 therebetween. The shutter 30 includes the first main surface 38a and a second main surface 38b as a pair of main surfaces each facing a respective one of each of the pairs of inner wall surfaces. At least one of the first main surface 38a or the second main surface 38b, (the second main surface 38b in the present example embodiment) has the second increased thickness portion 39b as an increased thickness portion that extends in the sliding direction of the shutter 30.

This feature makes it less likely for the electronic components M to enter the upper guide slit 41 and the lower guide slit 51, and facilitate smooth discharge of the electronic components M trough the discharge port 19.

In the case 1 according to the present example embodiment, the second increased thickness portion 39b extends over the entire length of the shutter 30 in the sliding direction.

Due to this feature, the second increased thickness portion 39b is reliably positioned in the opening 42 of the upper guide slit 41 and the opening 52 of the lower guide slit 51. Furthermore, when manufacturing the shutter 30, it is not necessary to form the second increased thickness portion 39b on separate portions of the shutter 30, thereby making the manufacturing easy.

In the case 1 according to the present example embodiment, the second increased thickness portion 39b preferably comes into contact with the upper inner wall surface 17b1 that faces the second increased thickness portion 39b.

This feature makes it still less likely for the electronic components M to fall in the lower guide slit 51. Furthermore, the shutter 30 slides while the second increased thickness portion 39b is in contact with the upper inner wall surface 17b1, whereby the shutter 30 can slide smoothly.

In the case 1 according to the present example embodiment, at least within the slide range from the position at which the shutter 30 closes the discharge port 19 to the position at which the shutter 30 leaves the discharge port 19 open, the second increased thickness portion 39b may be positioned in correspondence with the discharge port 19.

Due to this feature, the second increased thickness portion 39b has the minimum length required, thereby saving the material in the manufacturing.

In the case 1 according to the present example embodiment, it is preferable that the shutter 30 has a strip-shape having a constant width, and the second increased thickness portion 39b is provided at a central or substantially central portion of the shutter 30 in the width direction.

Due to this feature, in the case body 10 formed by combining the first members 2 and the second members 3, which are resin molded bodies, the second increased thickness portion 39b can be positioned in the central portion in the width direction, where a gap in the front-rear direction in the opening 52 of the lower guide slit 51 is largest. As a result, the second increased thickness portion 39b exerts a significant effect of reducing the tendency of the electronic components M to fall.

In the case 1 according to the present example embodiment, the shutter 30 includes an opening 31 that allows for opening the discharge port 19, and the opening 31 makes the second increased thickness portion 39b partially discontinuous in the sliding direction.

Due to this feature, in a state where the opening 31 coincides with the discharge port 19 and the discharge port 19 is open, the second increased thickness portion 39b is reliably positioned in both the upper guide slit 41 and the lower guide slit 51 that are respectively situated above and below the discharge port 19, thereby making it less likely for the electronic components M to fall into the upper guide slit 41 and the lower guide slit 51.

### Modifications

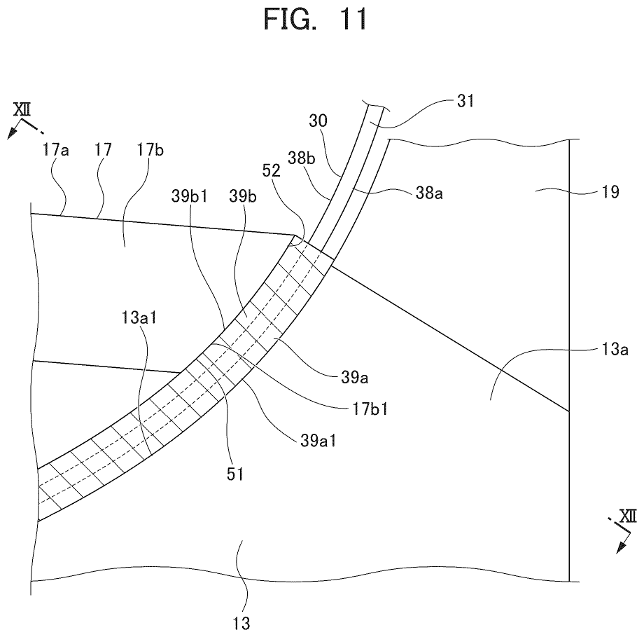

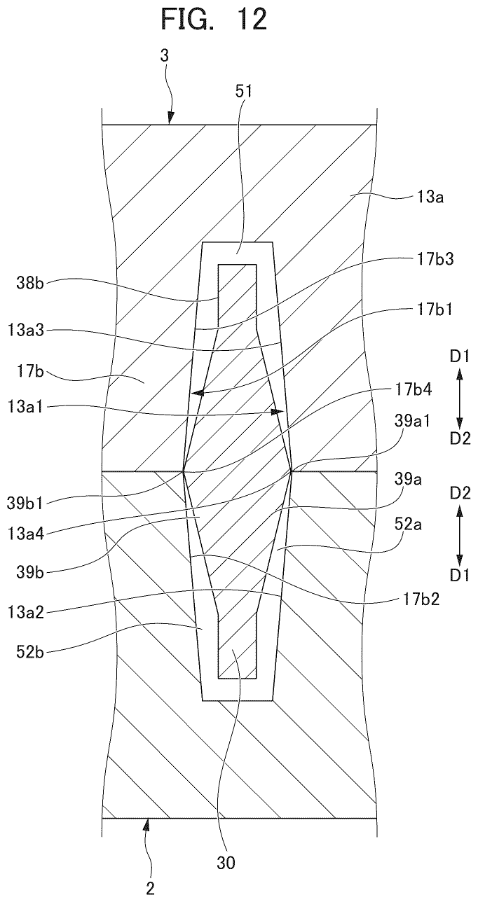

Next, a modification of the above example embodiment will be described with reference to FIGS. 11 and 12. The modification is different from the above example embodiment in that the first main surface 38a of the shutter 30 also has an increased thickness portion, and the rest of the configuration is the same as that of the above example embodiment. Therefore, in the following description, the same components as those of the above example embodiment are denoted by the same reference signs and the description thereof will be omitted, and the differences will be mainly described.

As illustrated in FIGS. 11 and 12, the shutter 30 of the modification has the second increased thickness portion 39b on the second main surface 38b and a first increased thickness portion 39a on the first main surface 38a.

The first increased thickness portion 39a includes a ridge that protrudes toward the outside of the case 1. The first increased thickness portion 39a has an isosceles triangular shape in a transverse cross section, like the second increased thickness portion 39b. The first increased thickness portion 39a is situated in a central portion in the width direction of the shutter 30, and has a first vertex 39a1 at the center in the width direction. The first increased thickness portion 39a is provided over the entire length of the shutter 30. Alternatively, similarly to the second increased thickness portion 39b illustrated in FIG. 10, the first increased thickness portion 39a may have a minimum length required such that within the slide range from the position at which the shutter 30 closes the discharge port 19 to the position at which the shutter 30 leaves the discharge port 19 open, the first increased thickness portion 39a is provided in correspondence with the opening 42 of the upper guide slit 41 and the opening 52 of the lower guide slit 51.

In the opening 52 of the lower guide slit 51, the first increased thickness portion 39a is positioned in the front gap 52a between the first main surface 38a of the shutter 30 and the lower inner wall surface 13a1. In a state where the shutter 30 has been inserted into the lower guide slit 51, the first vertex 39a1 of the first increased thickness portion 39a may come into contact with the groove bottom 13a4 of the lower inner wall surface 13a1.

The modification, in which the first increased thickness portion 39a is on the first main surface 38a of the shutter 30, makes it less likely for the electronic components M to fall through the front gap 52a into the lower guide slit 51. Accordingly, the electronic components M can be discharged more smoothly through the discharge port 19.

Moreover, according to the modification, in the case body 10 formed by combining the first members 2 and the second members 3, which are resin molded bodies, the first increased thickness portion 39a can be positioned in the central portion in the width direction, where the gap in the front-rear direction of the opening 52 of the lower guide slit 51 is largest. As a result, the first increased thickness portion 39a exerts a significant effect of reducing the tendency of the electronic components M to fall.

It should be noted that the present invention is not limited to the example embodiments and modifications described above, and modifications and improvements to example embodiments of the present invention are encompassed in the scope of the present invention.

For example, the cross-sectional shape of the increased thickness portion provided on at least one of the first main surface 38a or the second main surface 38b of the shutter 30 is not limited to a triangular shape, and may be an arbitrary shape. The number of increased thickness portions is not limited to one as in the example embodiments, and a plurality of increased thickness portions may be provided.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A case comprising:
a case body to accommodate a plurality of components and including a discharge port through which the components are dischargeable;
a guide slit in the case body and communicating with the discharge port; and
a shutter slidably inserted into the guide slit to slide to open and close the discharge port;
the case body including a pair of inner wall surfaces that face each other and define the guide slit therebetween;
the shutter including a pair of main surfaces that face the pair of inner wall surfaces, respectively, and including an increased thickness portion on at least one of the pair of main surfaces;
the increased thickness portion extending in a sliding direction in which the shutter slides.

2. The case according to claim 1, wherein the increased thickness portion extends over an entire length of the shutter in the sliding direction.

3. The case according to claim 1, wherein the increased thickness portion is contactable with the inner wall surface that faces the increased thickness portion.

4. The case according to claim 1, wherein the shutter includes the increased thickness portion on each of the pair of main surfaces.

5. The case according to claim 1, wherein at least within a sliding range from a position at which the shutter closes the discharge port to a position at which the shutter leaves the discharge port open, the increased thickness portion is provided in correspondence with the discharge port.

6. The case according to claim 1, wherein
the shutter has a strip-shape with a constant width; and
the increased thickness portion is provided at a central portion or a substantially central portion of the shutter in a width direction.

7. The case according to claim 1, wherein
the shutter includes an opening to allow for opening of the discharge port; and
the opening makes the increased thickness portion partially discontinuous in the sliding direction.

8. The case according to claim 1, wherein the increased thickness portion includes a ridge protruding toward an interior of the case.

9. The case according to claim 1, wherein the increased thickness portion has an isosceles triangular shape in a transverse cross section.

10. The case according to claim 1, wherein the increased thickness portion includes a vertex at a center or approximate center in a width direction.

11. The case according to claim 10, wherein the vertex is contactable with a groove bottom of one of the inner wall surfaces.

12. The case according to claim 1, wherein the increased thickness portion is positioned in a gap.

13. The case according to claim 12, wherein the increased thickness portion prevents the plurality of electronic components from falling through the gap.

14. The case according to claim 1, wherein a length of the increased thickness portion is less than a length of the shutter.

15. The case according to claim 1, wherein the guide slit includes an upper guide slit and a lower guide slit, and the increased thickness portion is capable of being positioned in both the upper guide slit and the lower guide slit.

16. The case according to claim 4, wherein the increased thickness portion on each of the pair of main surfaces has a same shape.

17. The case according to claim 4, wherein the increased thickness portion on each of the pair of main surfaces has an isosceles triangular shape in a transverse cross section.

18. The case according to claim 4, wherein the increased thickness portion on each of the pair of main surfaces extends over an entire length of the shutter in the sliding direction.

19. The case according to claim 4, wherein a length of the increased thickness portion on each of the pair of main surfaces is less than a length of the shutter.

20. The case according to claim 1, wherein a plurality of the increased thickness portion is provided.
